(19) United States
(12) Patent Application Publication
(10) Pub. No.: US 2026/0341634 A1
(43) Pub. Date: Oct. 29, 2026

(54) Auxiliary Plasma Excitation

(71) Applicant: Applied Materials, Inc., Santa Calra, CA (US)

(72) Inventors: Yuhui ZHANG, Sunnyvale, CA (US); Fernando SILVEIRA, Livermore, CA (US); Zhimin JIANG, Santa Clara, CA (US); Yue GUO, Redwood City, CA (US); A N M Wasekul AZAD, Cupertino, CA (US); Kartik RAMASWAMY, San Jose, CA (US); Yang YANG, Cupertino, CA (US)

(21) Appl. No.: 19/456,636

(22) Filed: Jan. 22, 2026

Related U.S. Application Data
(63) Continuation of application No. PCT/US2025/026205, filed on Apr. 24, 2025.

(51) Int. Cl. H01J 37/32

(52) U.S. Cl. CPC H01J 37/32091; H01J 37/321

(57) ABSTRACT

Methods and apparatus leverage electrodes and ring structures to aid plasma striking and sustaining. The apparatus may include an auxiliary plasma exciter positioned about and radially outward of an outermost coil of an ICP source of an ICP process chamber and an RF power source electrically connected to the auxiliary plasma exciter where the RF power source is independent of a power source for the ICP source. In some embodiments, the auxiliary plasma exciter may be a conductive ring structure with or without RF electrodes or RF electrodes alone. In some embodiments, positioned above the lid of the process volume of the process chamber, higher energies may be obtained by using the conductive ring structure or RF electrodes as part of a resonant circuit.

### CROSS-REFERENCE TO RELATED APPLICATIONS

This application claims the benefit of International Application No. PCT/US2025/026205, filed Apr. 24, 2025, and entitled “Auxiliary Plasma Excitation,” the contents of which are hereby incorporated by reference in their entirety.

### FIELD

Embodiments of the present principles generally relate to semiconductor processing of semiconductor substrates.

### BACKGROUND

With the semiconductor technology node advancing quickly towards sub-nanometer, the fabrication of complicated three-dimensional structures produces unprecedented challenges for the uniformity control of etching and deposition processes. To achieve processing with atomic precision across an entire wafer, extremely wide process windows are needed in terms of power, pressure, and gas chemistry, and the like. For low-power inductively couple plasma (ICP) processing with electronegative chemistry, processes often require long off times between pulses with ICP power as low as possible. The inventors have observed that in such a scenario, plasma density drops quickly between power pulses and restriking plasma or maintaining plasma stability becomes very challenging under such conditions.

Accordingly, the inventors have provided methods and apparatus for improving the striking and sustaining of plasma under challenging process chamber conditions.

### SUMMARY

Methods and apparatus for assisting excitation of plasma in ICP process chambers are provided herein.

In some embodiments, an apparatus for plasma generation in a process chamber may comprise an auxiliary plasma exciter positioned about and radially outward of an outermost coil of an ICP source of an ICP process chamber and an RF power source electrically connected to the auxiliary plasma exciter where the RF power source is independent of a power source for the ICP source.

In some embodiments, the apparatus may further include an auxiliary plasma exciter that is a conductive ring structure, a conductive ring structure that includes at least one capacitive element and where the conductive ring structure is configured to form a resonating circuit when energized by the RF power source, a conductive ring structure that is electrically connected to at least one RF electrode that is configured to capacitively couple to plasma in a process volume of the ICP process chamber, a conductive ring structure that has wavy portions that are configured to increase inductance of the resonating circuit, a conductive ring structure that has a gap at one position and is connected to the RF power source across the gap, a conductive ring structure that is positioned in a plane at or below a lowermost coil of the outermost coil of the ICP source, an auxiliary plasma exciter that is a plurality of electrodes that is configured to capacitively couple with plasma in a process volume of the ICP process chamber when energized by the RF power source, a plurality of electrodes that has each electrode electrically connected to one of a plurality of mutually coupled inductors positioned externally from the plurality of electrodes where the plurality of mutually coupled inductors are electrically connected to the RF power source and the plurality of electrodes and the plurality of mutually coupled inductors are configured to form resonating circuits when energized by the RF power source, each of the plurality of electrodes are connected to the RF power source via resonating circuits that are configured to resonate along with the plurality of electrodes when energized by the RF power source, an auxiliary plasma exciter that is an annular electrode positioned below a lid of the ICP process chamber and is configured to capacitively couple with plasma in a process volume of the ICP process chamber when energized by the RF power source, an auxiliary plasma exciter that is an annular electrode embedded in a lid of the ICP process chamber and is configured to capacitively couple with plasma in a process volume of the ICP process chamber when energized by the RF power source, and/or an annular electrode that has inwardly protruding spokes spaced around an inner perimeter of the annular electrode.

In some embodiments, an apparatus for plasma generation in a process chamber may comprise an auxiliary plasma exciter positioned about and radially outward of an outermost coil of an ICP source of an ICP process chamber where the auxiliary plasma exciter is a conductive ring structure and an RF power source electrically connected to the auxiliary plasma exciter where the RF power source is independent of a power source for the ICP source and the RF power source is configured to operate at a frequency different from the frequency of the power source of the ICP source.

In some embodiments, the apparatus may further include a conductive ring structure that includes at least one capacitive element and where the conductive ring structure is configured to form a resonating circuit when energized by the RF power source, a conductive ring structure that is electrically connected to at least one RF electrode and where the conductive ring structure is configured to capacitively couple to plasma in a process volume of the ICP process chamber, a conductive ring structure that has wavy portions that are configured to increase inductance of the resonating circuit where the conductive ring structure has a gap at one position and the conductive ring structure is connected to the RF power source across the gap or the conductive ring structure is positioned in a plane at or below a lowermost coil of the outermost coil of the ICP source, an auxiliary plasma exciter that is a plurality of electrodes that is configured to capacitively couple with plasma in a process volume of the ICP process chamber when energized by the RF power source, and/or a plurality of electrodes that has each electrode electrically connected to one of a plurality of mutually coupled inductors positioned externally from the plurality of electrodes where the plurality of mutually coupled inductors are electrically connected to the RF power source and the plurality of electrodes and the plurality of mutually coupled inductors are configured to form resonating circuits when energized by the RF power source.

In some embodiments, a method of plasma generation in a process chamber may comprise energizing at least one coil of an inductively coupled plasma (ICP) source of an ICP process chamber and energizing an auxiliary plasma exciter positioned about and radially outward of an outermost coil of the ICP source of the ICP process chamber with an RF power source electrically connected to the auxiliary plasma exciter where the RF power source is independent of a power source for the ICP source and at a different frequency than the power source of the ICP source.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 depicts a cross-sectional view of an inductively coupled plasma (ICP) process chamber in accordance with some embodiments of the present principles.

FIG. 2 depicts a cross-sectional view and a top-down view of an auxiliary plasma exciter with a conductive ring structure in accordance with some embodiments of the present principles.

FIG. 3 depicts top-down views of auxiliary plasma exciters with conductive ring structures in accordance with some embodiments of the present principles.

FIG. 4 depicts a cross-sectional view, a top-down view, and a schematic view of an auxiliary plasma exciter with electrodes and mutually coupled inductance in accordance with some embodiments of the present principles.

FIG. 5 depicts a cross-sectional view, a top-down view, and a schematic view of an auxiliary plasma exciter with electrodes and an external resonant circuit in accordance with some embodiments of the present principles.

FIG. 6 depicts a cross-sectional view and a top-down view of an auxiliary plasma exciter with under lid electrodes in accordance with some embodiments of the present principles.

FIG. 7 depicts a cross-sectional view and a top-down view of an auxiliary plasma exciter with an embedded conductive mesh in accordance with some embodiments of the present principles.

FIG. 8 is a graph of plasma generation using an auxiliary plasma exciter in accordance with some embodiments of the present principles.

FIG. 9 is a method of plasma generation in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and apparatus provide plasma auxiliary excitation to assist plasma striking and stability. The present techniques also facilitate enlarging the process windows for low-power, low-pressure semiconductor processing with long pulse OFF times. In some embodiments, an exciter ring structure can be installed with minimal retrofit cost that works in conjunction with the main ICP coils of the ICP process chamber without significant coupling with the main ICP coils. In some embodiments, embedded capacitively coupled plasma (CCP) electrodes may be embedded in or positioned above or below the lid of the ICP process chamber to achieve better coupling with the plasma in the process volume. The present techniques allow for wide process windows in terms of power, pressure, and gas chemistry and the like to achieve deposition and etching processing with atomic precision across an entire wafer. The tunability easily allows for compensation for electronegative chemistry used in logic applications and the like (e.g., maintaining stable plasma for pulse OFF times longer than 20 ms with ICP power less than 100 W with argon/chlorine gas).

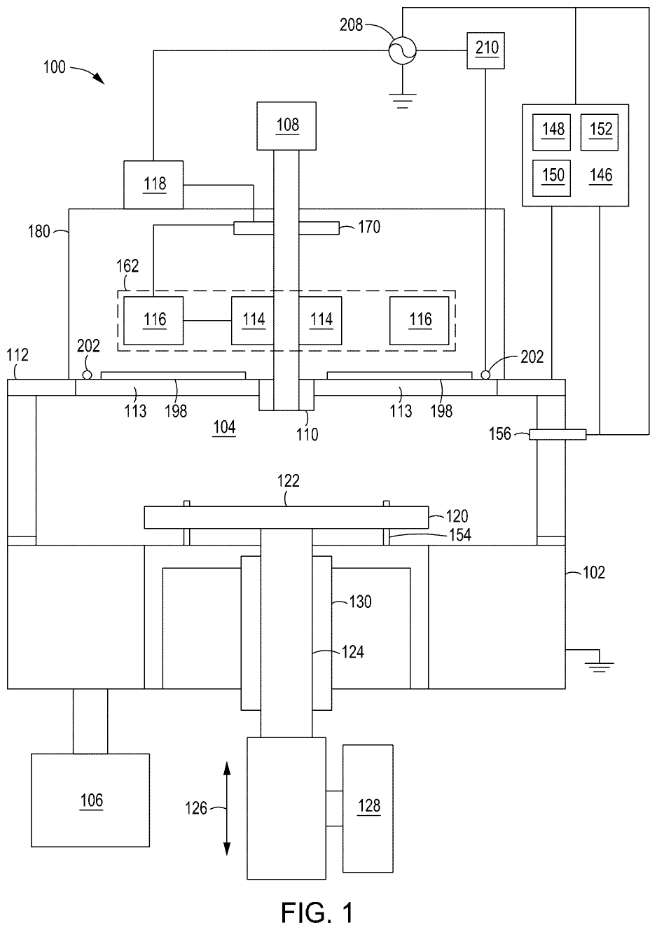

The present techniques incorporate auxiliary plasma exciters in ICP process chambers to help plasma striking and stability. An auxiliary plasma exciter, as used herein, is an apparatus used for striking or maintaining plasma in conjunction with the main ICP plasma coils (e.g., inner coils, outer coils, middle coils, etc., of the main ICP source) or without the main ICP plasma coils. In some embodiments, resonant circuits are used with the auxiliary plasma exciters to boost voltages to increase plasma striking and/or plasma sustaining performance. The present techniques provide additional process tuning knobs to alter the densities of charged particles and radicals as well as electromagnetic fields with the process volumes of inductively coupled plasma (ICP) process chambers. The varying techniques presented herein allow for cost effective retrofitting or easy incorporation into new chamber designs. FIG. 1 depicts a cross-sectional view of an example of an ICP chamber 100 in which the present techniques can be used but is not meant to be limiting. The ICP chamber 100 has a lid 112 that may be formed from an aluminum nitride or aluminum oxide-based material and the like and includes a dielectric window 113. A heater assembly 198 for the lid 112 may be positioned at or on the upper surface of the lid 112. The ICP chamber 100 includes an ICP source 180 which includes a coil assembly 162 and one or more RF plasma sources 118. The ICP chamber 100 includes chamber walls 102 that enclose a process volume 104 where substrate processing occurs. The ICP chamber 100 also includes a pumping system 106 to control the pressure within the ICP chamber 100 and to expel unwanted gases before, during, or after a substrate has been processed. The pumping system 106 may also include a throttling gate valve to assist in maintaining the pressure within the ICP chamber 100. In some instances, the pumping system 106 may also include a roughing pump for fast pump down and a turbomolecular pump for higher vacuum pressures.

A gas delivery system 108 provides process gases into the process volume 104 through a nozzle 110. The gas delivery system 108 may include showerheads, gas rings, and/or nozzles and the like. In some embodiments, plasma is inductively coupled in the process volume 104 using a coil assembly 162 with dual coil antennas that include one or more inner coils 114 and one or more outer coils 116. In some embodiments, the coil assembly 162 may have inner coils, middle coils (not shown), and outer coils. Plasma coupling power is provided by one or more RF plasma sources 118 with one or more frequencies, waveforms, and/or power levels, etc. If more than one frequency is used, the power may be generated by a single multi-channel RF generator or two separate RF generators that are synchronized. In some embodiments, the one or more RF plasma sources 118 may provide frequencies of approximately 100 kHz to approximately 250 MHz. The supplied RF power may be continuous and/or pulsed. The one or more RF plasma sources 118 may also include one or more RF match networks (not shown) positioned between the one or more RF plasma sources 118 and the coil assembly 162 for adjusting impedances of the power sources to match the load impedance of the ICP chamber 100 for optimal power transfer. In some embodiments, more than two RF sources may be used.

A power delivery adapter 170 may be connected to the one or more RF plasma sources 118 to distribute power to one or more outer coils 116. The one or more outer coils 116 are electrically connected to the one or more inner coils 114. In the example, which is not meant to be limiting, RF current flows from the one or more RF plasma sources 118 through the one or more outer coils 116 and then into the one or more inner coils 114 and then to the RF ground return. In some embodiments, the one or more RF plasma sources 118 may be first connected to the one or more inner coils 114 and RF current may flow first into the one or more inner coils 114 and then into the one or more outer coils 116 and then to the RF ground return. In some embodiments, an RF generator 208 and a matching network 210 may be used to power an auxiliary plasma exciter such as a conductive ring structure 202. The RF generator 208 and/or the matching network 210 may be connected to the controller 146 and/or to the one or more RF plasma sources 118 to synchronize power between the ICP coils and the auxiliary plasma exciter. Different embodiments may include different types of auxiliary plasma exciters and/or different auxiliary plasma exciter power configurations as described herein. FIG. 1 is but one example auxiliary plasma exciter power configuration, type, and position, and is not meant to be limiting. A pedestal 120 includes an upper portion 122 with lift pins 154 and a lower portion 124. The pedestal 120 may have vertical motion 126 provided by a lifting assembly 128. A bellows 130 allows the vertical motion 126 to occur without breaking the seal of the process volume 104. The ICP chamber 100 may also include a controller 146. In some embodiments, the controller 146 and/or RF generator 208 may interact with an optical sensor 156 such as an optical emissions spectroscopy (OES) sensor and the like to detect plasma states within the process volume 104.

The controller 146 controls the operation of the ICP chamber 100 using a direct control or alternatively, by controlling the computers (or controllers) associated with the ICP chamber 100. In operation, the controller 146 enables data collection and feedback to optimize performance of the ICP chamber 100. The controller 146 generally includes a Central Processing Unit (CPU) 148, a memory 150, and a support circuit 152. The CPU 148 may be any form of a general-purpose computer processor that can be used in an industrial setting. The support circuit 152 is conventionally coupled to the CPU 148 and may comprise a cache, clock circuits, input/output subsystems, power supplies, and the like. Software routines, such as used in the methods and/or apparatus as described herein may be stored in the memory 150 and, when executed by the CPU 148, transform the CPU 148 into a specific purpose computer (controller 146). The software routines may also be stored and/or executed by a second controller (not shown) that is located remotely from the ICP chamber 100.

The memory 150 is in the form of computer-readable storage media that contains instructions, when executed by the CPU 148, to facilitate the operation of the semiconductor processes and equipment. The instructions in the memory 150 are in the form of a program product such as a program that implements the apparatus of the present principles. The program code may conform to any one of a number of different programming languages. In one example, the disclosure may be implemented as a program product stored on a computer-readable storage media for use with a computer system. The program(s) of the program product may be used to define functions of the aspects of the present techniques disclosed herein. Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of ICP chamber 100 and/or auxiliary plasma exciter apparatus as described herein, are aspects of the present principles.

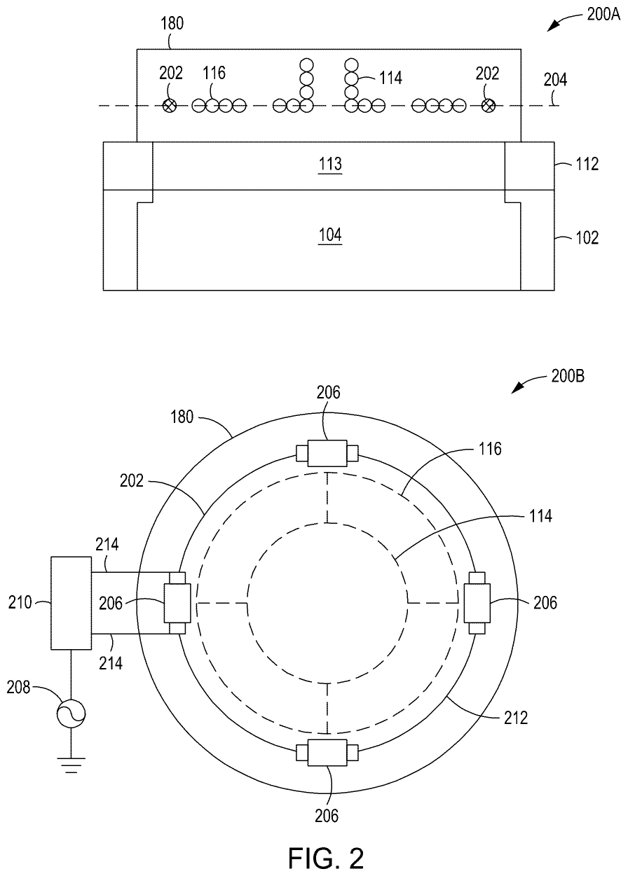

In some embodiments, an auxiliary plasma exciter such as a conductive ring structure 202 depicted in a view 200A of FIG. 2 is positioned radially outward of an outermost coil (e.g., outer coils 116) and at or below a horizontal plane 204 of the coils of the ICP process chamber. The conductive ring structure 202 provides auxiliary plasma excitation with the plasma in the process volume 104. The conductive ring structure 202 has a circular shape and 2 to 16 capacitors can be serially inserted into the conductive ring structure 202 symmetrically to achieve resonance at any desired frequency. In some embodiments, four capacitors 206 are inserted in the conductive ring structure 202 as depicted in a view 200B of FIG. 2. The segments 212 between capacitors 206 behave as inductors to resonate with capacitors 206 such that the overall resonate structure is an LC circuit. The resonate frequency should be different from the ICP coil frequencies to ensure decoupling between the ICP coils and the conductive ring structure 202. For example, ICP coil power is typically operated at a frequency of 13.56 MHz. The conductive ring structure 202 may be resonated at 60 MHz or 2 MHz (not meant to be limiting, as any frequency different from the coil frequency of 13.56 MHz would be sufficient to provide decoupling). The auxiliary plasma exciter (e.g., the conductive ring structure 202) is powered by an RF power source such as the RF generator 208 through the matching network 210. The power connection 214 (RF hot and ground connections) can be attached to any points on the conductive ring structure 202. In some embodiments, RF hot and a ground may be connected across one of the capacitors 206 (e.g., RF hot to one side of the capacitor and ground to another side of the capacitor). The applied RF power to the auxiliary plasma exciter (e.g., the conductive ring structure 202, etc.) may be from a few watts to hundreds of watts. In cases where the conductive ring structure 202 is used without capacitors 206, the ICP coils will form unwanted electromagnetic coupling between the conductive ring structure 202 and the ICP coils unless the conductive ring structure 202 is shielded from the ICP coils.

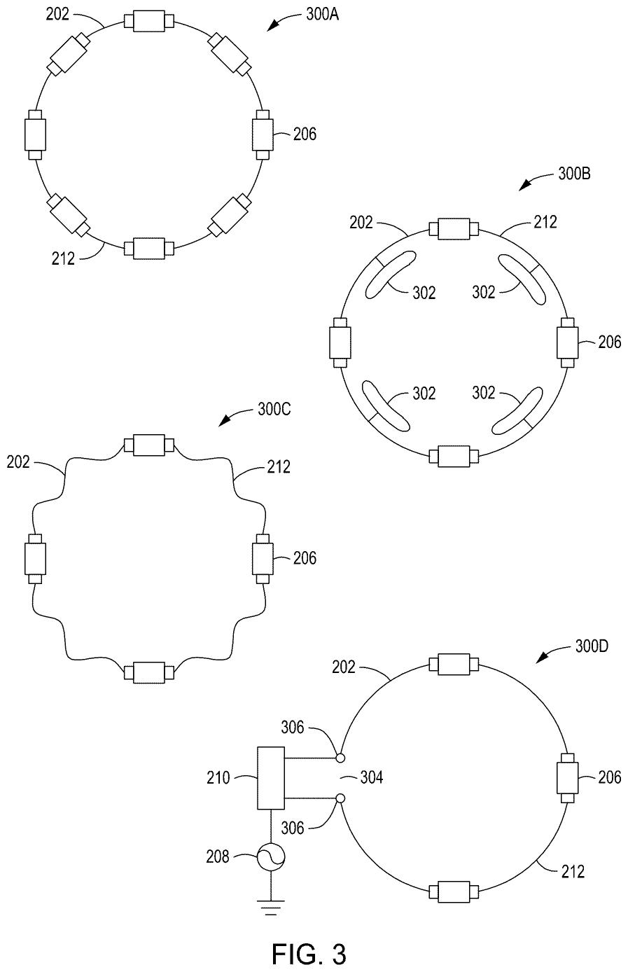

In a view 300A of FIG. 3, eight capacitors 206 are symmetrically distributed in series in the conductive ring structure 202. The plurality of capacitors 206 are used to minimize skew which may be caused by capacitively coupling from the high voltages across the capacitors. In a view 300B of FIG. 3, the conductive ring structure 202 has capacitors 206 and a plurality of electrodes 302. The electrodes may have pad-like feet that help capacitively couple the electrodes to plasma within the process volume 104 of the process chamber. The electrodes may extend inward and downward from the conductive ring structure 202 and radially outward from the outermost coils of the ICP source. The electrodes 302 enhance the capacitive coupling and the striking and re-striking capability of the auxiliary plasma exciter (e.g., the conductive ring structure 202). In a view 300C of FIG. 3, the segments 212 between the capacitors 206 are bent or made wavy to increase the length of the segments 212 between the capacitors 206 to increase the inductance of each of the segments 212. By increasing the inductance, the inductive coupling is increased as the capacitor value is reduced. By lengthening the segments 212, the auxiliary plasma exciter will also couple with a larger area of plasma in the process volume 104. In a view 300D of FIG. 3, the conductive ring structure 202 has an opening 304. The RF power input can be connected to both ends 306 (one end 306 to RF, one end 306 to ground). Removal of one or more of the capacitors 206 may be done to reduce high voltages for the associated area of plasma in the process volume 104 to reduce skew.

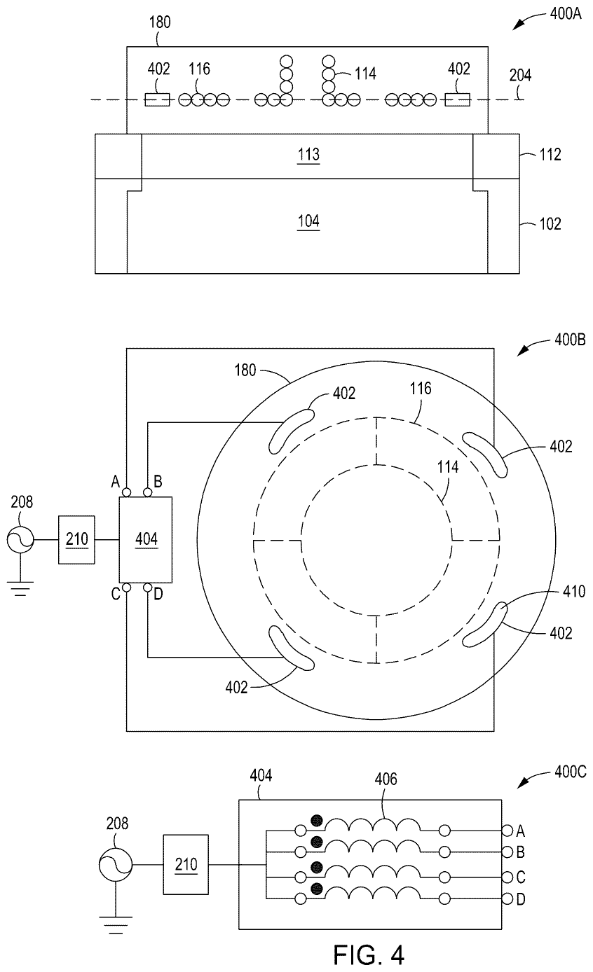

The following embodiments of FIGS. 4-6 as discussed below may be powered at any frequency as no inductive coupling occurs between the ICP coils and the electrodes. In some embodiments, instead of using a circular resonant ring (the conductive ring structure 202) for inductive coupling, electrodes 402 in conjunction with an inductor set 404 (forming an LC resonant circuit), may be used as the auxiliary plasma exciter for auxiliary plasma generation as depicted in FIG. 4. Any number of electrodes paired to any number inductors may be used. The electrodes 402 may be positioned radially outward of an outermost coil (e.g., outer coils 116) and at or below a horizontal plane 204 of the coils of the ICP process chamber as depicted in view 400A and 400B of FIG. 4. An issue with having multiple electrodes simultaneously coupled to plasma is that, due to plasma nonuniformity, one or more of the electrodes may tend to capacitively couple more power to the plasma, further deteriorating plasma uniformity. In some embodiments, an inductor set 404 with a plurality of inductors (one inductor electrically in series with one electrode) are mutually coupled to each other to self-balance the power delivery to individual electrodes as depicted in view 400B and view 400C of FIG. 4. The mutual coupling (sharing of the same magnetic flux between inductors) causes the same current flow through each of the inductors 406 and produces approximately the same voltages on each of the electrodes 402 (voltage differences between electrodes are minimized), improving plasma uniformity.

The inductor set 404 is positioned between the RF generator 208 and/or the matching network 210 and the electrodes 402. The inductor set 404 may be completely external to the ICP process chamber (e.g., mounted on the side or top, etc.) and no capacitors are required, eliminating the placement issues that can occur with positioning capacitors on the top of the lid 112, saving implementation and maintenance costs. In some embodiments, mutual coupling between the inductors 406 is achieved by winding a large inductor with a few cores (insulated to each other), each core can be separated out at the end for individual connection. The capacitance of the electrodes 402 and the inductance of the inductor set 404 forms an LC circuit which can be set to resonate at any frequency to maximize the voltage of the LC circuit. The inductor set 404 may also be manually and/or automatically adjusted to vary the resonant frequency based on, for example, chamber parameters and/or process profiles and the like. In some embodiments, the electrodes 402 may have pad-like ends that may be of any shape or size. The surface area 410 of the electrode ends may be adjusted to increase or decrease the density of the electric fields generated by the electrodes into the process volume 104 (larger surface area yields less density over larger area while smaller surface area yields higher density over smaller area). The size and placement of the electrodes 402 can be used to achieve higher plasma uniformity in the process volume 104. Another tuning knob is the vertical position of the electrodes 402 in relationship to the process volume 104. The closer the ends of the electrodes 402 to the process volume, the higher the capacitively coupling to the plasma within the process volume.

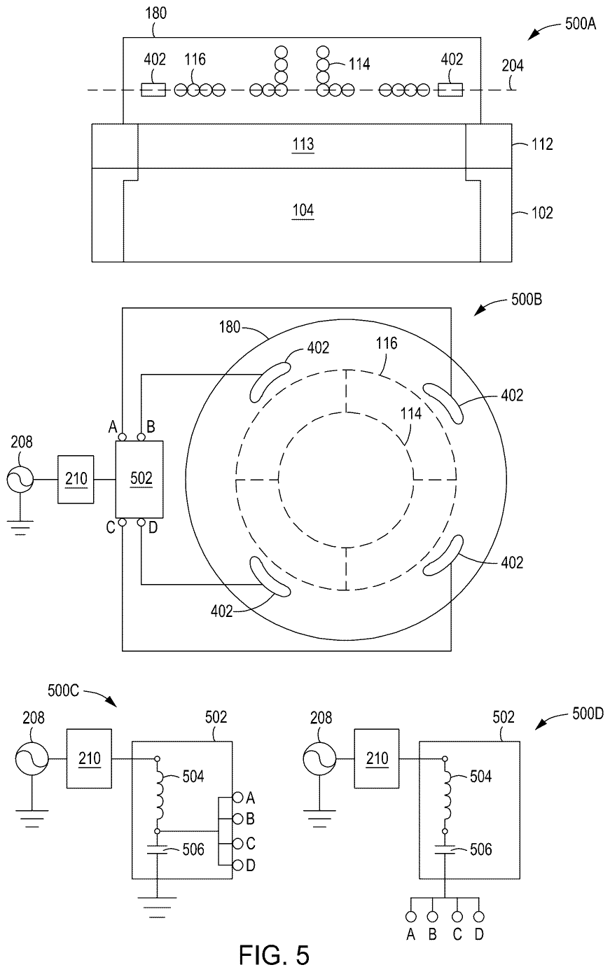

The electrodes 402 may be further enhanced apart from the mutually coupled inductors 406 to balance the power delivery as depicted in view 500A, view 500B, and view 500C of FIG. 5. In some embodiments, a resonate circuit 502 may be used to boost the striking voltage of the ICP process chamber as depicted in view 500B and view 500C of FIG. 5. For example, an LC series resonating circuit (resonate circuit 502) is inserted in series between the match network 210 and the electrodes 402. A high voltage will then be generated between the inductor 504 and the capacitor 506 in the resonate circuit 502, and the high voltage obtained by resonating the LC circuit can be used to increase striking performance of the auxiliary plasma exciter. The resonant circuit 502 may be completely external to the ICP process chamber and may be manually and/or automatically adjusted based on chamber parameters and/or process profiles and the like. In addition to the parallel connection between the capacitor 506 and the electrodes 402, a series connection may also be used to achieve the same function. In that case, the inductor 504, capacitor 506, and the electrodes 402 are connected in series as depicted in view 500D of FIG. 5. Implementation and maintenance costs are reduced as capacitors are not required to be installed on the lid 112.

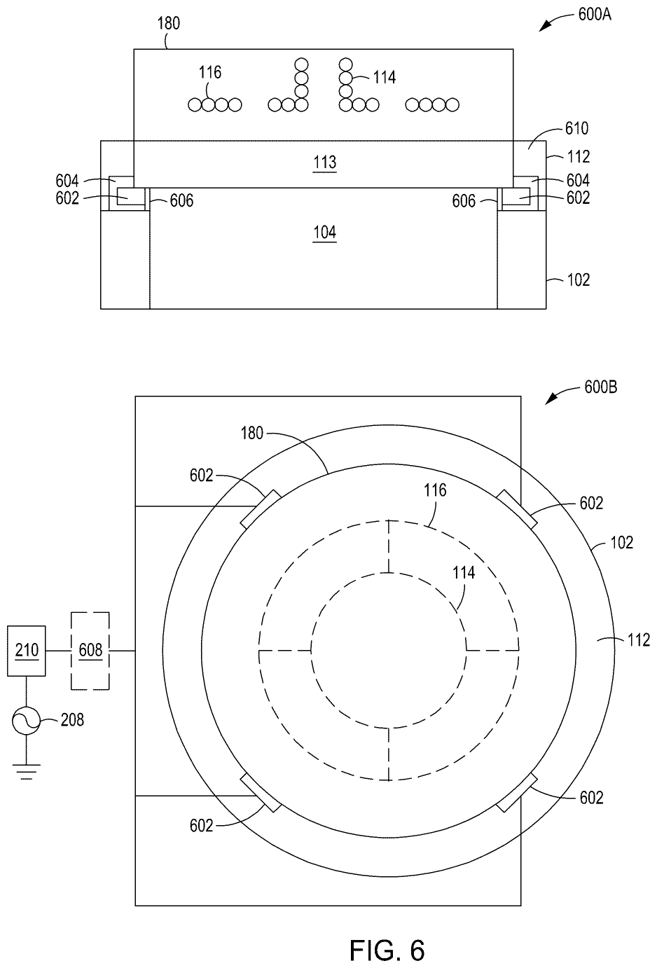

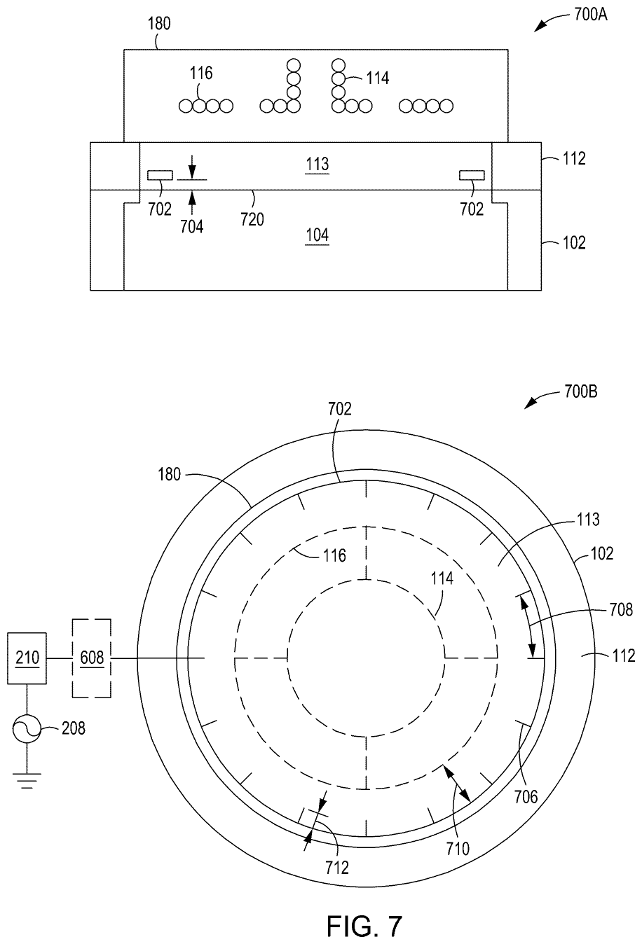

Placement of an auxiliary electrode is not limited to locations above the lid 112. Electrodes 602 can be positioned beneath the lid 112 and/or dielectric window 113 (see view 600A of FIG. 6) or embedded in the lid (see view 700A of FIG. 7) to increase capacitive coupling and reduce plasma-electrode separation (electrodes are closer to the plasma in the process volume 104 which increases capacitive coupling with the plasma). In some embodiments, the electrodes 602 may be used to generate electric fields to assist in plasma striking rather than plasma generation, allowing simplification of the supporting circuitry (no matching network, etc. needed). The use of the electrodes 602 is more cost effective in implementation as only minor changes to the lid are needed. In some embodiments, the electrodes 602 are positioned below the lid 112 and the dielectric window 113 as depicted in the view 600A. Any number of electrodes may be used and are positioned radially outward of the outer coils 116 of the ICP chamber. Because the electrodes 602 are conductive, the electrodes 602 are isolated by insulating material 604 from the lid ring 610 and the chamber walls 102. In some embodiments, the electrodes 602 will also have a protective element 606 separating the electrodes 602 from gases and/or plasma in the process volume 104.

The protective element 606 may be an insulator that is resistant to the harsh process volume environment to prevent corrosion or any type of detrimental effects to the electrodes 602. In some embodiments, the protective element 606 in contact with plasma may be made of ceramic material with appropriate coatings on the surfaces that come into contact with the plasma in the process volume 104. The electrodes 602 are powered by the RF generator 208 through the matching network 210. The electrodes 602 ignite the plasma to help the ICP coils to strike plasma and/or to maintain the plasma. The excitation frequency of the electrodes 602 may range from a few hundred hertz to the gigahertz range. Due to the enhanced capacitive coupling (the electrodes 602 are positioned closer to the plasma), the electrodes 602 may be powered with the RF generator 208 and the matching network 210 or by adding in an optional resonate circuit 608 (similar to the resonate circuit 502 of FIG. 5). In some embodiments, the electrodes 602 may be powered directly from the RF generator 208 without the matching network 210.

In some embodiments, the auxiliary plasma exciter may be an electrode comprising a layer of conductive mesh 702 that is embedded (e.g., sintered in the ceramic material) in the lid 112 around the edge of the lid 112 (dielectric window 113) as depicted in view 700A and view 700B of FIG. 7. The layer of conductive mesh 702 may be positioned a distance 704 from a few hundred mils above the bottom surface 720 of the lid 112 (dielectric window 113) to approximately an inch above the bottom surface 706 as depicted in view 700A. The layer of conductive mesh 702 serves as an auxiliary electrode of the auxiliary plasma exciter. Due to the enhanced capacitive coupling (positioned closer to the plasma and with a larger effective coupling area), the layer of conductive mesh 702 may be powered with the RF generator 208 and the matching network 210 or by adding in an optional resonate circuit 608 (similar to the resonate circuit 502 of FIG. 5). In some embodiments, the layer of conductive mesh 702 may be powered directly from the RF generator 208 without the matching network 210.

The shape of the layer of conductive mesh 702 is carefully designed to prevent generation of eddy currents from the inductive fields of the ICP coils. For example, to counter the inductive fields, the layer of conductive mesh 702 may be an outer ring-shaped mesh that connects with azimuthally distributed inwardly extending spokes 706 as depicted in view 700B of FIG. 7. The distance 710 between the outer ring to the outer most turn of the ICP coil (e.g., the outer coil 116) should be more than 1 inch to minimize inductive coupling between the ICP coils and the layer of conductive mesh 702. The length 712 of the spokes 706 may range from approximately 0.5″ to approximately 5″ and the spacing 708 (at the outer ring) may range from 0.1″ to 1″. The layer of conductive mesh 702 may be comprised of one or more materials such as a conductive mesh and/or a reinforcing material which is embedded and dispersed throughout the mesh. The material of the conductive mesh may comprise a single metal or two or more metals or metal alloys and the like. Metals which may be used include, but are not limited to, aluminum, magnesium, titanium, cobalt, cobalt nickel alloy, nickel, chromium, gold, silver and/or various combination thereof. The reinforcing material may be selected to provide a desired structural strength and may also be selected to provide desired values for other properties such as thermal conductivity or thermal expansion coefficient and the like. Examples of reinforcing materials include silicon, carbon, and/or silicon carbide, and the like, but other materials may also be used.

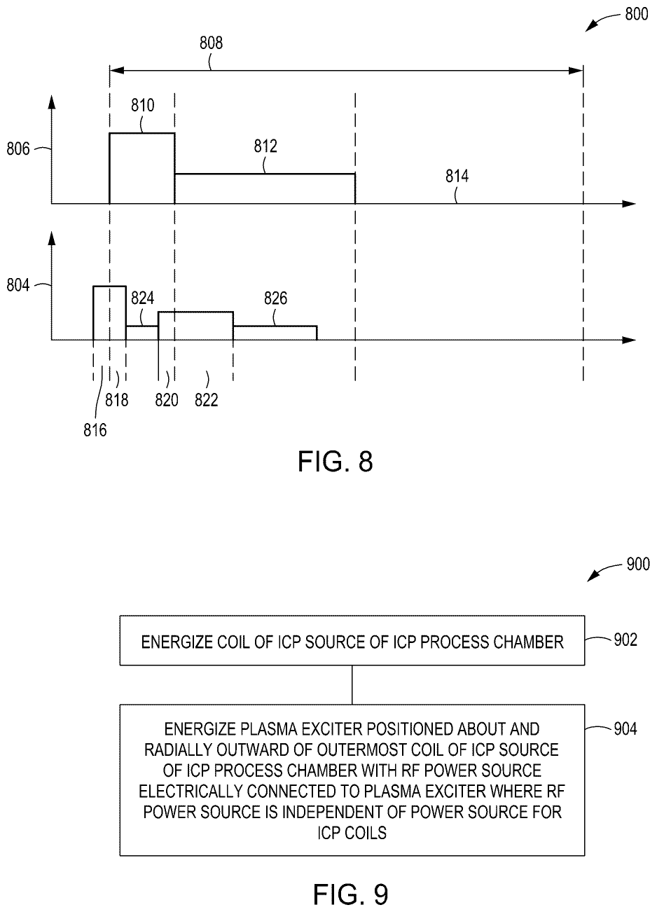

FIG. 8 is a graph 800 depicting example schemes of applying RF power to the auxiliary plasma exciter in relationship to the main ICP power that powers the ICP coils (e.g., the outer coils 116, the inner coils 114). The vertical axis of the graph 800 is amplitude and the horizontal axis is time. A single ICP power pulse has a pulse width 808. For a typical operating condition, the ICP power 806 to the ICP coils is pulsed at a certain frequency (e.g., 10's of Hz to kHz range, etc.) with multiple states: at a first power level for a first state 810 with a duty cycle from a few percent to tens of a percent; at a second power level during a second state 812 with a duty cycle from a few percent to tens of a percent; zero power applied at third state 814 with a duty cycle derived from the first state 810 and the second state 812. Either the second state 812 or the third state 814 may be absent or more states could be added to meet process requirements. Based on the example ICP power scheme of FIG. 8, the auxiliary plasma exciter power (Dt) 804 may be applied at each pulsing cycle: 1) at Dt1 816 prior to the first state 810 of the ICP power 806-Dt1 816 may be from a few microseconds to seconds range; 2) Dt2 818 into the first state 810 of the ICP power 806-Dt2 818 may be from a few microseconds to be the same duration as the first state 810 of the ICP power 806 and depends on the requirement of maintaining plasma stability by the process being implemented; and 3) Dt3 820 and Dt4 822 are decided based on the same principles with Dt1 810 and Dt2 818. In some embodiments, feedback with regard to the state of the plasma in the process volume 104 may be obtained, for example, by the optical sensor 156 (e.g., optical emission spectroscopy sensor, etc.) directly and/or indirectly (via the controller 146, etc.). The feedback can be used to indicate when the plasma has reached stability and the auxiliary plasma exciter adjusted accordingly (e.g., initial striking pulse Dt2 818 reduced, auxiliary sustaining power applied Dt5 824, etc.). Feedback can also be used to adjust the power levels of the auxiliary plasma exciter for each of the states dynamically.

Each ICP power state may be accompanied by the auxiliary plasma exciter power based on the same principle. The auxiliary plasma exciter RF power can be applied during the first state 810 or the second state 812 at different power levels other than that depicted for Dt1/Dt2 or Dt3/Dt4. For example, during Dt5 824, the power level of the auxiliary plasma exciter is lower than the power level in Dt2 818. Likewise, during Dt6 826, the power level of the auxiliary plasma exciter is lower than the power level in Dt3 820 and Dt4 822. Ideally, the applied auxiliary plasma exciter power should be able to enable plasma striking and stability but be as low as possible to minimize lid sputtering and as short as possible in the time domain (duration). The auxiliary plasma exciter RF power level may range from a few watts to hundreds of watts. If the auxiliary plasma exciter power is used to generate radicals or charged particles to facilitate the processing in the chamber, then power can be increased to a desired amount and can even be turned on anytime during the processing, not necessarily accompanied with the ICP power for the ICP coils.

FIG. 9 is a method 900 of plasma generation in a process chamber. In block 902, the coils of an ICP source of an ICP process chamber are energized. In block 904, an auxiliary plasma exciter positioned about and radially outward of an outermost coil of an ICP source of the ICP process chamber is energized with an RF power source that is electrically connected to the auxiliary plasma exciter and is independent of the power source for the ICP coils. In some embodiments, the ICP coil power source and the auxiliary plasma exciter power source may be synchronized either directly or indirectly (e.g., via the controller 146 of FIG. 1, etc.). In some embodiments, the auxiliary plasma exciter may be an electrode type that can support operating the auxiliary plasma exciter power and the ICP coil power at the same frequencies (no inductive coupling occurs). If inductive coupling can occur between the ICP coils and the auxiliary plasma exciter, different frequencies can be used for the power sources of the auxiliary plasma exciter and the ICP coils or shielding can be used. The auxiliary plasma exciter may include conductive ring structures and/or electrodes and the like. Various configurations as described herein may be used based on the type of processing being performed in the ICP chamber and/or based on cost and difficulty of retrofitting to existing chambers, etc. The methods and apparatus herein provide ways of plasma auxiliary excitation that increase the process window and plasma stability of ICP process chambers. The auxiliary plasma exciter with the conductive ring structure can be used to generate high voltage to help plasma striking without coupling to the ICP coils. In addition, auxiliary plasma exciters using embedded CCP electrodes under the lid and/or embedded in the lid can achieve superior capacitive coupling with plasma in the process volume of the ICP chamber.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. An apparatus for plasma generation in a process chamber, comprising:
an auxiliary plasma exciter positioned about and radially outward of an outermost coil of an ICP source of an ICP process chamber; and
an RF power source electrically connected to the auxiliary plasma exciter, wherein the RF power source is independent of a power source for the ICP source.

2. The apparatus of claim 1, wherein the auxiliary plasma exciter is a conductive ring structure.

3. The apparatus of claim 2, wherein the conductive ring structure includes at least one capacitive element and wherein the conductive ring structure is configured to form a resonating circuit when energized by the RF power source.

4. The apparatus of claim 3, wherein the conductive ring structure is electrically connected to at least one RF electrode that is configured to capacitively couple to plasma in a process volume of the ICP process chamber.

5. The apparatus of claim 3, wherein the conductive ring structure has wavy portions that are configured to increase inductance of the resonating circuit.

6. The apparatus of claim 3, wherein the conductive ring structure has a gap at one position and is connected to the RF power source across the gap.

7. The apparatus of claim 3, wherein the conductive ring structure is positioned in a plane at or below a lowermost coil of the outermost coil of the ICP source.

8. The apparatus of claim 1, wherein the auxiliary plasma exciter is a plurality of electrodes that is configured to capacitively couple with plasma in a process volume of the ICP process chamber when energized by the RF power source.

9. The apparatus of claim 8, wherein the plurality of electrodes has each electrode electrically connected to one of a plurality of mutually coupled inductors positioned externally from the plurality of electrodes, wherein the plurality of mutually coupled inductors are electrically connected to the RF power source, and wherein the plurality of electrodes and the plurality of mutually coupled inductors are configured to form resonating circuits when energized by the RF power source.

10. The apparatus of claim 8, wherein each of the plurality of electrodes are connected to the RF power source via resonating circuits that are configured to resonate along with the plurality of electrodes when energized by the RF power source.

11. The apparatus of claim 1, wherein the auxiliary plasma exciter is an annular electrode positioned below a lid of the ICP process chamber and is configured to capacitively couple with plasma in a process volume of the ICP process chamber when energized by the RF power source.

12. The apparatus of claim 1, wherein the auxiliary plasma exciter is an annular electrode embedded in a lid of the ICP process chamber and is configured to capacitively couple with plasma in a process volume of the ICP process chamber when energized by the RF power source.

13. The apparatus of claim 12, wherein the annular electrode has inwardly protruding spokes spaced around an inner perimeter of the annular electrode.

14. An apparatus for plasma generation in a process chamber, comprising:
an auxiliary plasma exciter positioned about and radially outward of an outermost coil of an ICP source of an ICP process chamber, wherein the auxiliary plasma exciter is a conductive ring structure; and
an RF power source electrically connected to the auxiliary plasma exciter, wherein the RF power source is independent of a power source for the ICP source and wherein the RF power source is configured to operate at a frequency different from the frequency of the power source of the ICP source.

15. The apparatus of claim 14, wherein the conductive ring structure includes at least one capacitive element and wherein the conductive ring structure is configured to form a resonating circuit when energized by the RF power source.

16. The apparatus of claim 15, wherein the conductive ring structure is electrically connected to at least one RF electrode and wherein the conductive ring structure is configured to capacitively couple to plasma in a process volume of the ICP process chamber.

17. The apparatus of claim 15, wherein the conductive ring structure has wavy portions that are configured to increase inductance of the resonating circuit, wherein the conductive ring structure has a gap at one position and wherein the conductive ring structure is connected to the RF power source across the gap, or wherein the conductive ring structure is positioned in a plane at or below a lowermost coil of the outermost coil of the ICP source.

18. The apparatus of claim 14, wherein the auxiliary plasma exciter is a plurality of electrodes that is configured to capacitively couple with plasma in a process volume of the ICP process chamber when energized by the RF power source.

19. The apparatus of claim 18, wherein the plurality of electrodes has each electrode electrically connected to one of a plurality of mutually coupled inductors positioned externally from the plurality of electrodes, wherein the plurality of mutually coupled inductors are electrically connected to the RF power source, and wherein the plurality of electrodes and the plurality of mutually coupled inductors are configured to form resonating circuits when energized by the RF power source.

20. A method of plasma generation in a process chamber, comprising:
energizing at least one coil of an inductively coupled plasma (ICP) source of an ICP process chamber; and
energizing an auxiliary plasma exciter positioned about and radially outward of an outermost coil of the ICP source of the ICP process chamber with an RF power source electrically connected to the auxiliary plasma exciter, wherein the RF power source is independent of a power source for the ICP source and at a different frequency than the power source of the ICP source.
